(19) United States
(12) Patent Application Publication
(10) Pub. No.: US 2025/0008852 A1
(43) Pub. Date: Jan. 2, 2025

(54) TWO-TERMINAL FERROELECTRIC PEROVSKITE DIODE MEMORY ELEMENT

(71) Applicant: Intel Corporation, Santa Clara, CA (US)

(72) Inventors: Punyashloka Debashis, Hillsboro, OR (US); Dominique A. Adams, Portland, OR (US); Gauri Auluck, Hillsboro, OR (US); Scott B. Clendenning, Portland, OR (US); Arnab Sen Gupta, Hillsboro, OR (US); Brandon Holybee, Portland, OR (US); Raseong Kim, Portland, OR (US); Matthew V. Metz, Portland, OR (US); Kevin P. O'Brien, Portland, OR (US); John J. Plombon, Portland, OR (US); Marko Radosavljevic, Portland, OR (US); Carly Rogan, North Plains, OR (US); Hojoon Ryu, Hillsboro, OR (US); Rachel A. Steinhardt, Beaverton, OR (US); Tristan A. Tronic, Aloha, OR (US); I-Cheng Tung, Hillsboro, OR (US); Ian Alexander Young, Olympia, WA (US); Dmitri Evgenievich Nikonov, Beaverton, OR (US)

(73) Assignee: Intel Corporation, Santa Clara, CA (US)

(21) Appl. No.: 18/346,212

(22) Filed: Jul. 1, 2023

(51) Int. Cl. H10N 70/00; H10B 63/00; H10B 99/00

(52) U.S. Cl. CPC H10N 70/8836; H10B 63/20; H10B 63/80; H10B 99/16; H10B 99/22; H10N 70/021; H10N 70/841

(57) ABSTRACT

A two-terminal ferroelectric perovskite diode comprises a region of ferroelectric perovskite material positioned adjacent to a region of n-type doped perovskite semiconductor material. Asserting a positive voltage across the diode can cause the polarization of the ferroelectric perovskite material to be set in a first direction that causes the diode to be placed in a low resistance state due to the formation of an accumulation region in the perovskite semiconductor material at the ferroelectric perovskite-perovskite semiconductor boundary. Asserting a negative voltage across the diode can cause the polarization of the ferroelectric perovskite material to be set in a second direction that causes the diode to be placed in a high resistance state due to the formation of a depletion region in the perovskite semiconductor material at the ferroelectric perovskite-perovskite semiconductor material. These non-volatile low and high resistance states enable the diode to be used as a non-volatile memory element.

### BACKGROUND

In some existing and emerging memory technologies, two-terminal devices capable of low possessing low and high resistance states can be used as memory elements in crossbar array memories. Perovskite materials are a class of materials that have the general chemical formula of ABX₃ (comprising mostly of oxides (X=oxygen)). Perovskite materials have the same crystal structure and a similar lattice constant.

### BRIEF DESCRIPTION OF THE DRAWINGS

FIGS. 1A-1B illustrate schematic views of a ferroelectric perovskite diode in high and low resistance states and corresponding energy band diagrams.

FIG. 2 illustrates an energy band diagram of the ferroelectric perovskite material of an example ferroelectric perovskite diode.

FIG. 3 illustrates a cross-sectional view of an example ferroelectric perovskite diode.

FIG. 4 is a schematic illustration of an example crossbar array utilizing ferroelectric perovskite diodes.

FIG. 5 is an example method a forming a ferroelectric perovskite diode.

FIG. 6 is a top view of a wafer and dies that may be included in a microelectronic assembly, in accordance with any of the embodiments disclosed herein.

FIG. 7 is a cross-sectional side view of an integrated circuit device that may be included in a microelectronic assembly, in accordance with any of the embodiments disclosed herein.

FIGS. 8A-8D are perspective views of example planar, FinFET, gate-all-around, and stacked gate-all-around transistors.

FIGS. 9A and 9B are perspective and cross-sectional views of example forksheet gate-all-around transistors.

FIGS. 10A and 10B are perspective and cross-sectional views of an example complementary field-effect-transistor (CFET) architecture.

FIG. 11 is a cross-sectional side view of an integrated circuit device assembly that may include one or more of the microelectronic assemblies disclosed herein.

FIG. 12 is a block diagram of an example electrical device that may include a microelectronic assembly, in accordance with any of the embodiments disclosed herein.

### DETAILED DESCRIPTION

Disclosed herein are two-terminal ferroelectric perovskite diodes that can be used as memory elements. The ferroelectric perovskite diodes comprise a first region comprising a ferroelectric perovskite material positioned adjacent to a second region comprising an n-type doped perovskite semiconductor. Asserting a positive voltage of sufficient magnitude across the diode can cause the polarization of the ferroelectric perovskite material to be aligned in a first direction that causes the diode to be placed in a low resistance state due to the formation of an accumulation region in the perovskite semiconductor material at the ferroelectric perovskite-perovskite semiconductor interface. Asserting a negative voltage of sufficient magnitude across the diode can cause the polarization of the ferroelectric perovskite material to be aligned in a second direction opposite to the first direction that causes the diode to be placed in a high resistance state due to the formation of a depletion region in the perovskite semiconductor at the ferroelectric perovskite-perovskite semiconductor interface. These ferroelectric perovskite diodes can be used as memory elements (e.g., bits) with the high and low resistance states representing “zero” and “one” logic states. The ferroelectric perovskite diodes can be used in, for example, crossbar arrays.

The ferroelectric perovskite diodes disclosed herein can have at least the following advantages. They can have a lower switching voltage (lower coercive voltage), a larger “on” current (the current of the diode in its low resistance state), and an “on” current wither great non-linearity than memories comprising other two-terminal ferroelectric devices as memory elements, such as ferroelectric tunnel junctions (FTJs). FTJ-based memories can suffer from difficulty in sensing the state of a memory bit due to an FTJ's low “on” current and the lack of a highly non-linear current-voltage (I-V) characteristic, which can require the use of a selector device in series with an FTJ in each memory cell, which can impact the size of an FTJ memory cell. In contrast, the relatively high non-linearity of the I-V characteristics of the disclosed ferroelectric perovskite diodes in the diode's low-resistance state can obviate the need for selector devices and ferroelectric perovskite diode-based memories may have a smaller memory cell size and small overall memory size relative to FTJ-based memory cells and memories. Thus, the ferroelectric perovskite diodes of the type disclosed herein can allow for high-density energy-efficient memories.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact with each other and “coupled” may indicate elements co-operate or interact with each other, but they may or may not be in direct physical or electrical contact. Furthermore, the terms “comprising,” “including,” “having,” and the like, as used with respect to embodiments of the present disclosure, are synonymous.

Terms modified by the word “substantially” include arrangements, orientations, spacings, or positions that vary slightly from the meaning of the unmodified term. For example, the portion of a first layer or feature that is substantially perpendicular to a second layer or feature can include a first layer or feature that is +/−20 degrees from a second layer or feature, a first surface that is substantially parallel to a second surface can include a first surface that is within several degrees of parallel from the second surface, and a layer that is substantially planar can include layers that comprise some dishing, bumps, or other non-planar features resulting from processing variations and/or limitations. Values and upper and lower range limits preceded by the word “about” include values within 10% of the indicated values and range limits.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

Certain terminology may also be used herein for the purpose of reference only, and thus are not intended to be limiting. For example, terms such as “upper,” “lower,” “above,” “below,” “bottom,” “top”, “lateral” and “vertical” refer to directions in the Figures to which reference is made. Terms such as “front,” “back,” “rear,” and “side” describe the orientation and/or location of portions of the component within a consistent but arbitrary frame of reference which is made clear by reference to the text and the associated Figures describing the component under discussion. Such terminology may include the words specifically mentioned above, derivatives thereof, and words of similar import.

As used herein, the term “integrated circuit component” refers to a packaged or unpacked integrated circuit product. A packaged integrated circuit component comprises one or more integrated circuit dies mounted on a package substrate with the integrated circuit dies and package substrate encapsulated in a casing material, such as a metal, plastic, glass, or ceramic. In one example, a packaged integrated circuit component contains one or more processor units mounted on a substrate with an exterior surface of the substrate comprising a solder ball grid array (BGA). In one example of an unpackaged integrated circuit component, a single monolithic integrated circuit die comprises solder bumps attached to contacts on the die. The solder bumps allow the die to be directly attached to a printed circuit board. An integrated circuit component can comprise one or more of any computing system component described or referenced herein or any other computing system component, such as a processor unit (e.g., system-on-a-chip (SoC), processor core, graphics processor unit (GPU), accelerator, chipset processor), I/O controller, memory, or network interface controller.

Reference is now made to the drawings, which are not necessarily drawn to scale, wherein similar or same numbers may be used to designate same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well known structures and devices are shown in block diagram form in order to facilitate a description thereof. The intention is to cover all modifications, equivalents, and alternatives within the scope of the claims

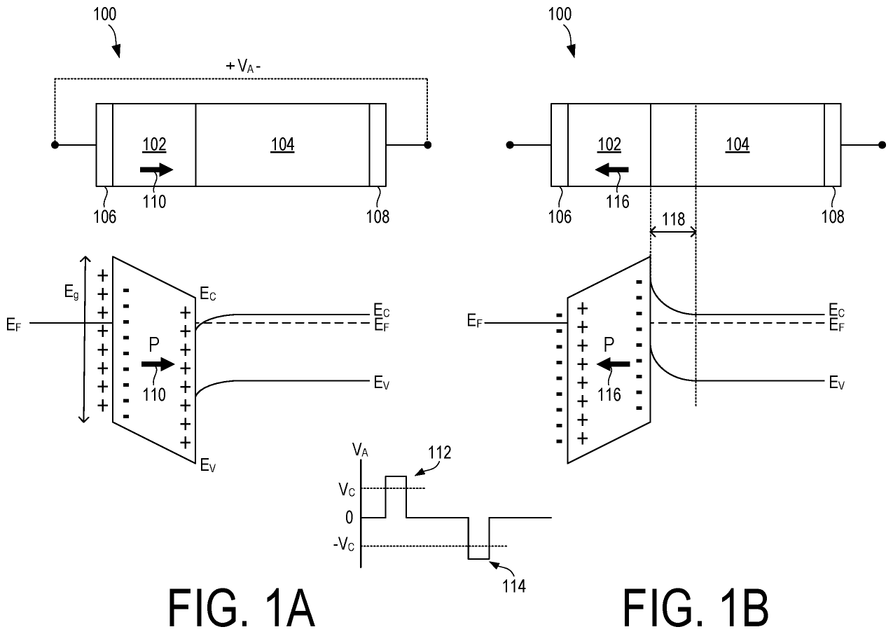

FIGS. 1A-1B illustrate schematic views of a ferroelectric perovskite diode in high and low resistance states and corresponding energy band diagrams. The ferroelectric perovskite diode 100 is a two-terminal device comprising a first region 102 comprising a ferroelectric perovskite material positioned adjacent to a second region 104 comprising an n-type doped perovskite semiconductor material. Electrodes 106 and 108 of the diode 100 also comprise perovskite materials and are positioned adjacent to the first region 102 and the second region 104, respectively.

As illustrated in FIG. 1A, the application of an applied voltage V_{A} across the electrodes 106 and 108 comprising a positive pulse 112 having sufficient magnitude to cause the voltage across the first region 102 to exceed the coercive voltage V_{C} of the ferroelectric perovskite region causes the polarization of the ferroelectric perovskite material to be set in a first direction (indicated by arrows 110). Setting the polarization of the ferroelectric perovskite material in the first region 102 in the first direction causes an accumulation region to be formed in the perovskite semiconductor at the interface between the ferroelectric perovskite-perovskite semiconductor regions due to the attraction of electrons in the perovskite semiconductor to the ferroelectric perovskite material, as indicated by the bending of the conduction E_{C} and valence energy bands E_{V} in the energy band diagram of FIG. 1A.

As illustrated in FIG. 1B, the application of a negative pulse 114 having sufficient magnitude to cause the voltage across the first region 102 to exceed the coercive voltage V_{C} of the ferroelectric perovskite region causes the polarization of the ferroelectric perovskite material to be set in a second direction (indicated by arrows 116) that is opposite to the first polarization direction. Setting the polarization of the ferroelectric perovskite material in the first region 102 in the second direction causes the formation of a depletion (or space charge) region 118 in the perovskite semiconductor at the ferroelectric perovskite-perovskite semiconductor interface due to repulsion of electrons from the interface, as indicated by the bending of the conduction and valence energy bands in the perovskite semiconductor in FIG. 1B.

The total resistance across the diode 100 when the polarization of the ferroelectric perovskite is in the first direction (when an accumulation layer is formed in the perovskite semiconductor material) is lower than the total resistance across the diode 100 when the polarization of the ferroelectric perovskite is in the second direction (when a depletion layer is formed in the perovskite semiconductor material). The diode 100 thus has application as a memory element, with the two resistance states corresponding to “zero” and “ones” logic states. Asserting a positive or negative pulse across the diode with sufficient magnitude to set the polarization of the ferroelectric perovskite can be considered to be a “write” operation and detecting or sensing the resistance of the memory element (without causing the polarization of the memory element to be set) can be considered to be a read operation. As the polarization of the ferroelectric perovskite is maintained until the polarization is next caused to be switched through the application of a subsequent positive or negative voltage pulse having sufficient magnitude, the ferroelectric perovskite diode can be utilized as a non-volatile memory element.

The ferroelectric perovskite material of the first region 102 can comprise barium titanate (BaTiO₃ (BTO), a material comprising barium, titanium, and oxygen), zirconium-doped barium titanate (BaZrₓTi₁₋ₓO₃), calcium-doped barium titanate (Ba₁₋ₓCaₓ)TiO₃, strontium-doped barium titanate (Ba₁₋ₓSrₓTiO₃), calcium and zirconium co-doped barium titanate (Ba₁₋ₓCaₓTi_{1-y}Zr_{y}O₃), hafnium-doped barium titanate (BaHfₓTi₁₋ₓO₃), bismuth ferrite (BiFeO₃ (BFO), a material comprising bismuth, iron, and oxygen), lanthanum-doped bismuth ferrite (Bi₁₋ₓLaₓFeO₃), cobalt-doped bismuth ferrite (BiFe₁₋ₓCoₓO₃), lithium niobate (LiNbO₃, a material comprising lithium, niobium, and oxygen), potassium niobate (KNbO₃, a material comprising potassium, niobium, and oxygen), GdFeO₃ (a material comprising gadolinium, iron, and oxygen), and lanthanum-doped GdFeO₃ (Gd₁₋ₓLaₓFeO₃), or another suitable ferroelectric perovskite material. The doped ferroelectric perovskite materials are lightly doped, with values for x and y in the chemical formulas for the ferroelectric perovskite materials listed in this paragraph being about 0.3 or less. Put another way, the doping level of any dopant in the ferroelectric perovskite material is 0.3% or less.

In other embodiments, the ferroelectric perovskite material can comprise the alloy Ba₁₋ₓSrₓSnO₃ (where x is not limited to values of about 0.3 of less).

In some embodiments, the coercive voltage of the first region is about 100 mV, in a range of about 80 mV to 300 mV, or in a range of about 100 mV to about 3 V. In some embodiments, the coercive voltage of the first region can be tailored through the selection of ferroelectric perovskite material used for the first region and/or the thickness of the first region.

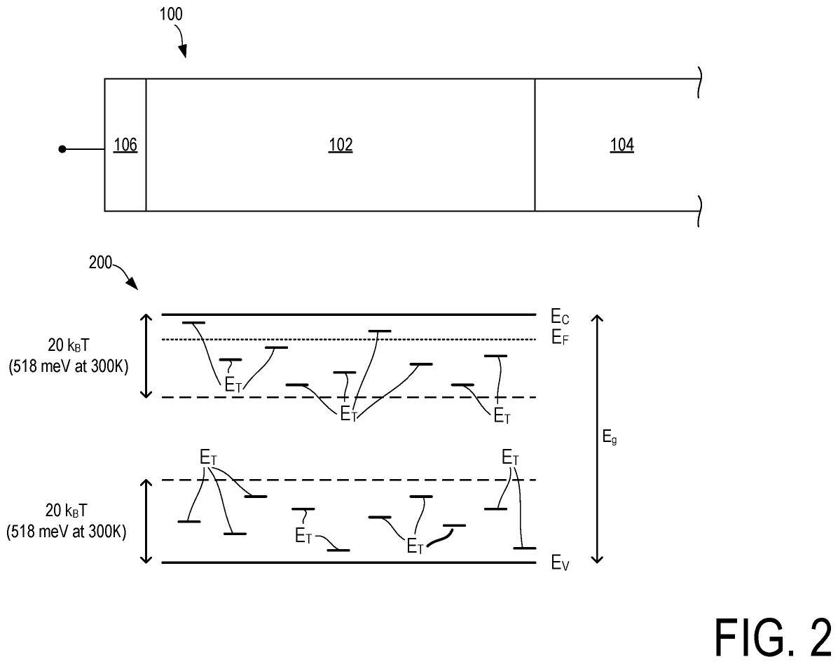

The ferroelectric perovskite material of the first region 102 comprises moderately shallow isolated trap states (represented as trap energy levels ET in FIG. 2) that lie within the bandgap E_{g} of the ferroelectric perovskite material, as indicated within in FIGS. 1A and 1B. The trap states can form during formation (e.g., growth) of the ferroelectric perovskite layer and are within about 20 V_{T} (thermal voltage) of the ferroelectric perovskite material's conduction and valence band energy levels, as described below. The presence of moderately shallow trap states can increase the conductivity of a ferroelectric perovskite material and can provide for ferroelectric perovskite diodes that have an “on” current density greater than FTJs. The dominant conduction mechanism in ferroelectric perovskite diodes with moderately shallow isolated trap isolated can be Poole Frenkel conduction, and conduction through the first region via this conduction mechanism can be referred to as a leakage current. The trap states are isolated within the ferroelectric perovskite material in that they are physically localized within the ferroelectric perovskite material. The isolated trap states are located throughout the ferroelectric perovskite material and thus provide a conduction path for charge carriers through the first region. The ferroelectric perovskite can have one or more trap state energy levels.

FIG. 2 illustrates an energy band diagram of the ferroelectric perovskite material of an example ferroelectric perovskite diode. In some embodiments, at least one trap energy level E_{T} in the ferroelectric perovskite of the first region 102 is located within the range of about 20 V_{T} (where V_{T} is the thermal voltage k_{B}T/q, k_{B} is Boltzmann's constant and q is the electrical charge of an electron). At 300 K, V_{T} is about 25.9 meV and 20 V_{T} is about 518 meV. Thus, in some embodiments, the ferroelectric perovskite material of the first region has at least one trap level E_{T} in its energy band gap within 518 meV of its conduction band or valence band levels, as illustrated in FIG. 2. The presence of a large leakage current across a ferroelectric perovskite diode can indicate the presence of moderately shallow trap states in the ferroelectric perovskite region. The existence of trap states in the ferroelectric perovskite material allows it to have a larger conductivity than some insulating ferroelectric materials, such as hafnium zirconium oxide (HZO), that make those insulating ferroelectric materials unattractive candidates for use in a ferroelectric diode. In some embodiments, the presence of moderately shallow isolated trap states in the ferroelectric perovskite region of the perovskite diodes described herein can result in diodes having a current density of about 1.0×10⁻³ A/cm² or greater at 300 K, the current density based on a cross-sectional area of the first region perpendicular to the direction of current flow through the first region.

Control of the concentration of moderately shallow traps within the ferroelectric perovskite region can control the conductivity of the ferroelectric perovskite region. The formation of trap states in a ferroelectric perovskite material can be compensated for by depositing a ferroelectric perovskite material under low-pressure conditions. This results in adatoms with high kinetic energy that can create knock-on damage, which can compensate for the shallow trap states and reduce the leakage current across the ferroelectric perovskite material. The ferroelectric perovskite diodes disclosed herein take advantage of this leakage current and a conductive ferroelectric perovskite region can be formed by controlling the oxygen pressure (or overall deposition pressure) when forming the ferroelectric perovskite layer such that shallow trap states are left uncompensated, with higher oxygen pressure generally resulting in a higher amount of trap states. The presence of shallow trap states in the ferroelectric perovskite material may not reduce its ferroelectric polarization properties. An increase in the polarization of ferroelectric perovskite materials has been observed in ferroelectric perovskite materials grown under high oxygen pressure conditions. By placing a ferroelectric perovskite region whose conduction can be controlled by processing conditions in series with perovskite semiconductor to create a ferroelectric perovskite diode, the overall current of which can be determined by the space charge limited current, which is controlled by the polarization-dependent formation or lack of a depletion layer in the perovskite semiconductor.

The n-type doped perovskite semiconductor material of the second region 104 can comprise barium tin oxide (BaSnO₃, a material comprising barium, tin, and oxygen) lightly doped with lanthanum (Ba₁₋ₓLnₓSnO₃ (LBSO)), strontium (Ba₁₋ₓSrₓSnO₃), or antimony (BaSn₁₋ₓSbₓO₃); strontium stannate (SrSnO₃, a material comprising strontium, tin, and oxygen) lightly doped with lanthanum, tantalum, neodymium, samarium, niobium, antimony, or lead; strontium titanate (SrTiO₃, a material comprising strontium, titanium, and oxygen) doped with lanthanum (Sr_{1-x x}LnₓTiO₃) or vanadium (SrVₓTi₁₋ₓO₃); or another n-type doped perovskite material. The n-type doped ferroelectric perovskite semiconductors are lightly doped, with values for x in the chemical formulas for the n-type doped perovskite semiconductors listed in this paragraph being about 0.1 or less. Put another away, the doping level of the n-type dopant in the ferroelectric semiconductor material is about 0.1% or less.

The perovskite electrodes 106 and 108 can comprise a metallic perovskite oxide such as strontium ruthenate (SrRuO₃, also referred to as SRO, which is a material that comprises strontium, ruthenium, and oxygen), SrVO₃ (which is a material that comprises strontium, vanadium, and oxygen), SrCrO₃ (which is a material that comprises strontium, chromium, and oxygen), strontium ferrite (SrFeO₃, which is a material that comprises strontium, iron, and oxygen), sodium tungsten bronze (NaWO₃, which is a material that comprises sodium, tungsten, and oxygen), KMoO₃ (which is a material that comprises potassium, molybdenum, and oxygen), strontium niobate (SrNbO₃, which is a material that comprises strontium, niobium, and oxygen), lanthanum titanate (LaTiO₃, which is a material that comprises lanthanum, titanium, and oxygen), LaWO₃ (which is a material that comprises lanthanum, tungsten, and oxygen), niobium-doped strontium titanate (Nb-doped SrTiO₃, also referred to as Nb-STO, which is a material that comprises niobium, strontium, titanium, and oxygen), lanthanum strontium manganite (La₁₋ₓSrₓMnO₃, also referred to as LSMO, which is a material that comprises lanthanum, strontium, manganese, and oxygen), or another suitable metallic perovskite oxide. In some embodiments, the first electrode 106 and the second electrode 108 can comprise the same perovskite oxide and in other embodiments, the first electrode 106 and the second electrode 108 can comprise different perovskite oxides.

As the ferroelectric, semiconductor, and metal electrode regions of the diodes all comprise perovskite materials, they are lattice-matched, which can provide processing advantages, such as a low amount of crystal defects in regions near boundaries between perovskite materials relative to regions in material boundaries where the materials have non-matching lattice structures and/or non-matching lattice constants.

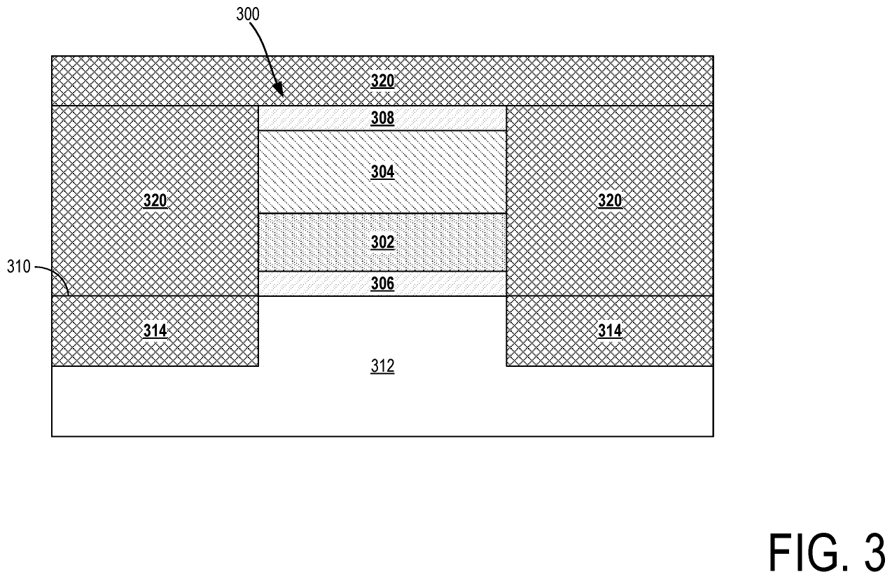

FIG. 3 illustrates a cross-sectional view of an example ferroelectric perovskite diode. The diode 300 comprises a first region 302 comprising a ferroelectric perovskite material positioned adjacent to a second region 304 comprising an n-type doped perovskite semiconductor material. The diode 300 further comprises perovskite electrodes 306 and 308 positioned adjacent to the first and second regions 302 and 304, respectively. The first region 302 is positioned between the first electrode 306, and the second region 304 and the second region 304 is positioned between the first region 302 and the second electrode 308. The diode 300 is located on a surface 310 of a substrate 312. The substrate 312 comprises dielectric regions 314. Dielectric regions 320 are positioned laterally adjacent to and above the diode 300. The substrate 312 can comprise any of the materials that can be part of any substrate described or referenced herein, such as die substrate 1102. The dielectric regions 314 and 320 can comprise a suitable nitride or oxide, such as silicon nitride (Si₃N₄), silicon dioxide (SiO₂), carbon-doped silicon dioxide (C-doped SiO₂, also known as CDO or organosilicate glass, which is a material that comprises silicon, oxygen, and carbon), fluorine-doped silicon dioxide (F-doped SiO₂, also known as fluorosilicate glass, which is a material that comprises fluorine, silicon, and oxygen), hydrogen-doped silicon dioxide (H-doped SiO₂, which is a material that comprises silicon, oxygen, and hydrogen).

Although the diode 300 is illustrated in FIG. 3 as being located on the surface 310 of the substrate 312, in other embodiments, the diode 300 can be formed between metal layers in an integrated circuit. For example, the first electrode 306 can be positioned adjacent to a conductive trace of a first interconnect layer (e.g., an M1 layer) and/or the second electrode 308 can be positioned adjacent to a conductive trace of a second interconnect layer (e.g., an M2 layer). In some embodiments, an electrode of a diode can be connected to and conductively coupled to a conductive trace of an interconnect layer by a via.

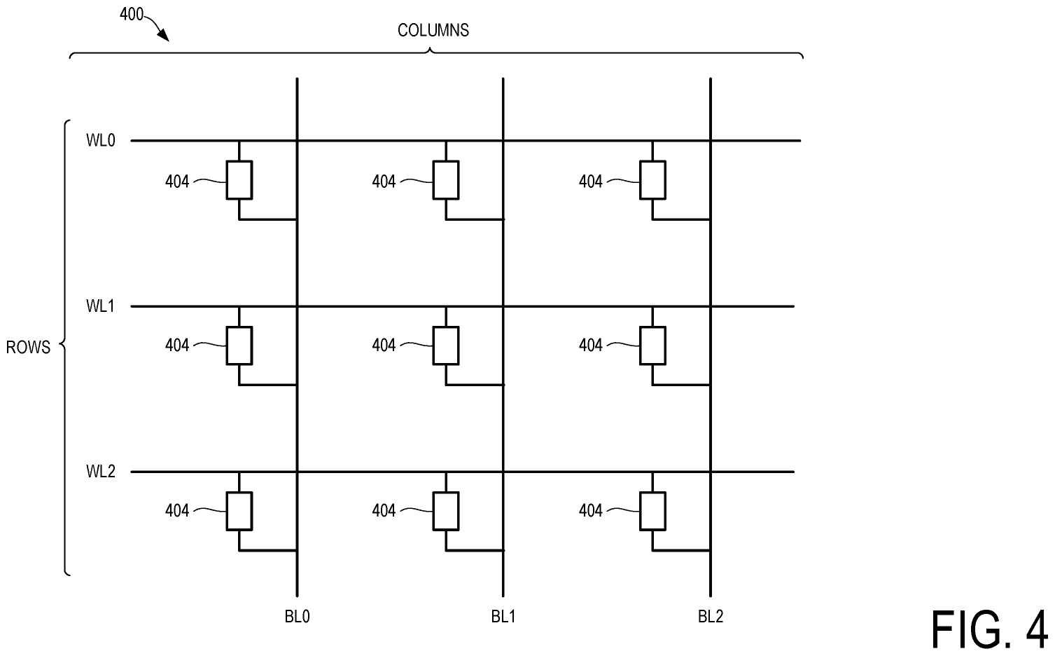

FIG. 4 is a schematic illustration of an example crossbar array comprising ferroelectric perovskite diodes as memory elements. The array 400 comprises nine ferroelectric perovskite diodes 404 arranged in a 3×3 array. Each of the word lines WL0, WL1, and WL2 are connected to first electrodes of the diodes 404 in a row and each of the bit lines BL0, BL1, and BL2 are connected to second electrodes of diodes 404 belonging to a column. A diode 404 can be written to through assertion of a positive or negative voltage pulse across the word line and bit line connected to diode to be written to. A diode 404 can be read from by detecting the resistance of the diode 404 by, for example, asserting a voltage on the word line connected to the diode to be read from and determining resistance of the diode through use of a voltage divider, sense amplifier, or other suitable memory cell read circuitry. The ferroelectric perovskite diodes described herein can be used as a memory element in any memory or storage device, memory circuit, memory integrated circuit component, or another integrated circuit component described or referenced herein.

The perovskite diodes described herein can be used in any processor unit or integrated circuit component described or referenced herein. An integrated circuit component comprising perovskite diodes can be attached to a printed circuit board (motherboard, mainboard). In some embodiments, one or more additional integrated circuit components or other components (e.g., battery, memory, antenna) can be attached to the printed circuit board. In some embodiments, the printed circuit board and the integrated circuit component can be located in a computing device that comprises a housing that encloses the printed circuit board and the integrated circuit component.

The ferroelectric perovskite diodes disclosed herein can be located on the same integrated circuit die with any of the field effect transistor types of devices described or referenced herein (e.g., planar, FinFET, GAAFET, stacked GAAFET, forksheet device, CFET device).

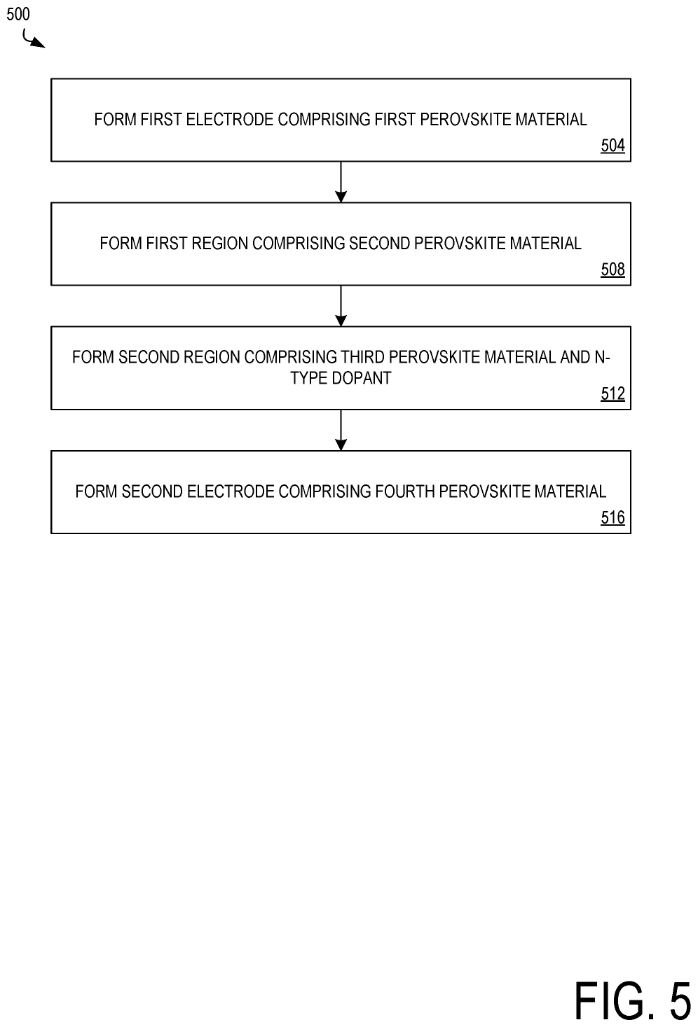

FIG. 5 is an example method of forming a ferroelectric perovskite diode. The method 500 can be performed by, for example, an integrated circuit component manufacturer. At 504, a first electrode comprising a first perovskite material is formed. At 508, a first region comprising a second perovskite material is formed, the first region positioned adjacent to the first electrode. At 512, a second region comprising a third perovskite material and an n-type dopant for the third perovskite material is formed, the second region positioned adjacent to the first region, the first region positioned between the first electrode and the second region. At 516, a second electrode comprising a fourth perovskite material is formed, the second electrode positioned adjacent to the second region, the second region positioned between the first region and the second electrode.

In other embodiments, the method 500 may have additional elements. For example, the method 500 can further comprise forming a conductive trace of a metallization layer, wherein the first electrode is formed after formation of the conductive layer, the first electrode positioned adjacent to the conductive trace and between the conductive trace and the first region. In another example, the method 500 can further comprise forming a conductive trace of a metallization layer after formation of the second electrode, wherein the second electrode is positioned adjacent to the conductive trace and between the conductive trace and the second region.

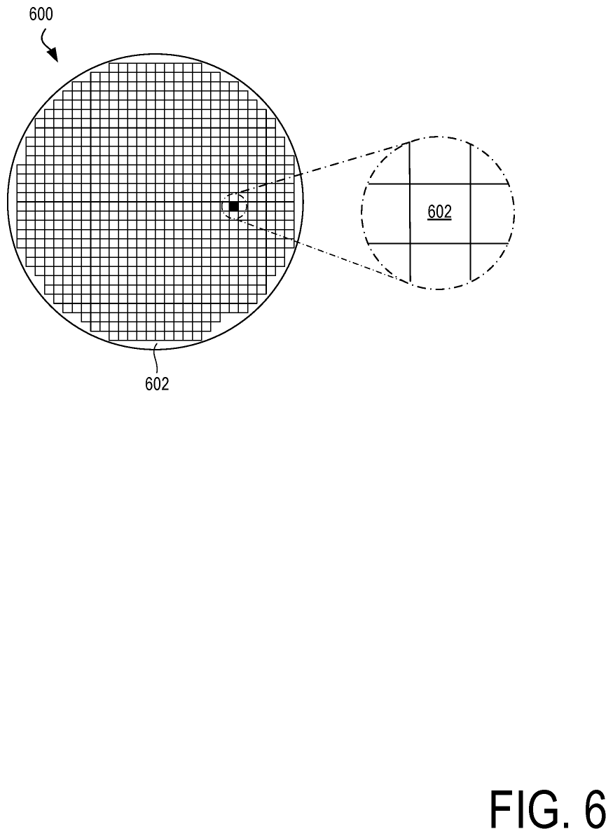

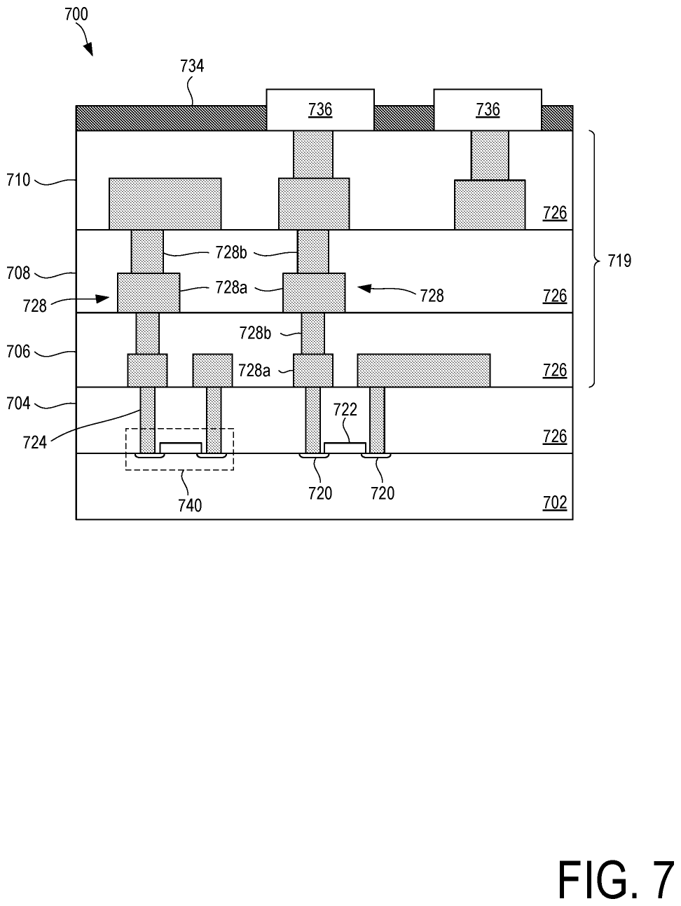

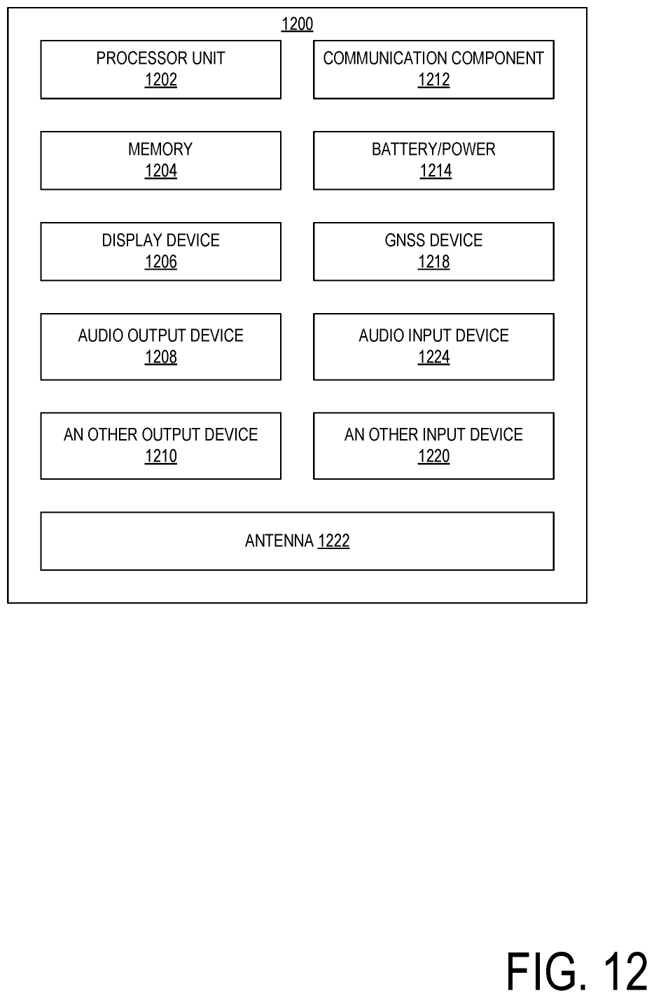

FIG. 6 is a top view of a wafer 600 and dies 602 that may be included in any of the microelectronic assemblies disclosed herein. The wafer 600 may be composed of semiconductor material and may include one or more dies 602 having integrated circuit structures formed on a surface of the wafer 600. A die 600 can comprise any of the ferroelectric perovskite diodes disclosed herein. The individual dies 602 may be a repeating unit of an integrated circuit product that includes any suitable integrated circuit. After the fabrication of the semiconductor product is complete, the wafer 600 may undergo a singulation process in which the dies 602 are separated from one another to provide discrete “chips” of the integrated circuit product. The die 602 may include one or more transistors (e.g., some of the transistors 740 of FIG. 7, discussed below), supporting circuitry to route electrical signals to the transistors, passive components (e.g., signal traces, resistors, capacitors, or inductors), and/or any other integrated circuit components. In some embodiments, the wafer 600 or the die 602 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 602. For example, a memory array formed by multiple memory devices may be formed on a same die 602 as a processor unit (e.g., the processor unit 1202 of FIG. 12) or other logic that is configured to store information in the memory devices or execute instructions stored in the memory array. Various ones of the microelectronic assemblies disclosed herein may be manufactured using a die-to-wafer assembly technique in which some dies 602 are attached to a wafer 600 that include others of the dies 602, and the wafer 600 is subsequently singulated.

FIG. 7 is a cross-sectional side view of an integrated circuit device 700 that may be included in any of the microelectronic assemblies disclosed herein. One or more of the integrated circuit devices 700 may be included in one or more dies 602 (FIG. 6). The integrated circuit device 700 may be formed on a die substrate 702 (e.g., the wafer 600 of FIG. 6) and may be included in a die (e.g., the die 602 of FIG. 6). The die substrate 702 may be a semiconductor substrate composed of semiconductor material systems including, for example, n-type or p-type materials systems (or a combination of both). The die substrate 702 may include, for example, a crystalline substrate formed using a bulk silicon or a silicon-on-insulator (SOI) substructure. In some embodiments, the die substrate 702 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 702. Although a few examples of materials from which the die substrate 702 may be formed are described here, any material that may serve as a foundation for an integrated circuit device 700 may be used. The die substrate 702 may be part of a singulated die (e.g., the dies 602 of FIG. 6) or a wafer (e.g., the wafer 600 of FIG. 6).

The integrated circuit device 700 may include one or more device layers 704 disposed on the die substrate 702. The device layer 704 may include features of one or more transistors 740 (e.g., metal oxide semiconductor field-effect transistors (MOSFETs)) formed on the die substrate 702. The transistors 740 may include, for example, one or more source and/or drain (S/D) regions 720, a gate 722 to control current flow between the S/D regions 720, and one or more S/D contacts 724 to route electrical signals to/from the S/D regions 720. The transistors 740 may include additional features not depicted for the sake of clarity, such as device isolation regions, gate contacts, and the like. The transistors 740 are not limited to the type and configuration depicted in FIG. 7 and may include a wide variety of other types and configurations such as, for example, planar transistors, non-planar transistors, or a combination of both.

Non-planar transistors may include FinFET transistors (such as double-gate transistors or tri-gate transistors) and wrap-around or gate-all-around transistors (such as nanoribbon, nanosheet, or nanowire transistors). Devices comprises non-planar transistors may include forksheet transistor and complementary FET (CFET) devices.

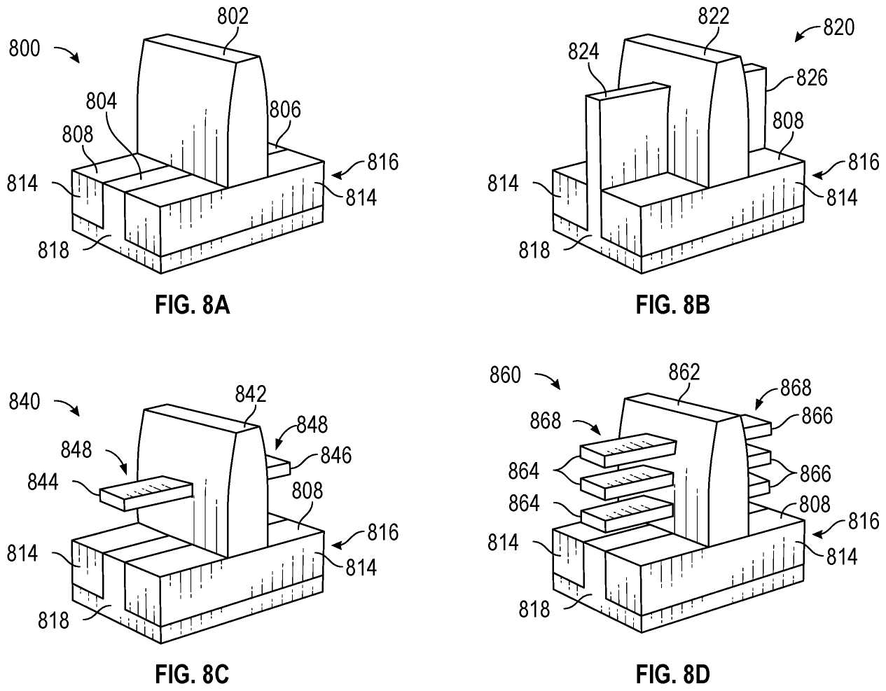

FIGS. 8A-8D are simplified perspective views of example planar, FinFET, gate-all-around, and stacked gate-all-around transistors. The transistors illustrated in FIGS. 8A-8D are formed on a substrate 816 having a surface 808. Dielectric regions 814 separate the source and drain regions of the transistors from other transistors and from a bulk region 818 of the substrate 816.

FIG. 8A is a perspective view of an example planar transistor 800 comprising a gate 802 that controls current flow between a source region 804 and a drain region 806. The transistor 800 is planar in that the source region 804 and the drain region 806 are planar with respect to the substrate surface 808.

FIG. 8B is a perspective view of an example FinFET transistor 820 comprising a gate 822 that controls current flow between a source region 824 and a drain region 826. The transistor 820 is non-planar in that the source region 824 and the drain region 826 comprise “fins” that extend upwards from the substrate surface 828. As the gate 822 encompasses three sides of the semiconductor fin that extends from the source region 824 to the drain region 826, the transistor 820 can be considered a tri-gate transistor. FIG. 8B illustrates one S/D fin extending through the gate 822, but multiple S/D fins can extend through the gate of a FinFET transistor.

FIG. 8C is a perspective view of a gate-all-around (GAA) transistor (GAAFET) 840 comprising a gate 842 that controls current flow between a source region 844 and a drain region 846 of a strip 1148 comprising a semiconductor (semiconductor strip). The transistor 840 is non-planar in that the strip 1148 is elevated from the substrate surface 828.

FIG. 8D is a perspective view of a GAA transistor 860 comprising a gate 862 that controls current flow between source regions 864 and drain regions 866 of multiple elevated semiconductor strips 1168. The transistor 860 is a stacked GAA transistor as the gate controls the flow of current between multiple elevated S/D regions stacked on top of each other. The transistors 840 and 860 can be referred to as gate-all-around transistors as the gates encompass all sides of the portions of the semiconductor strips that extend from the source regions to the drain regions. The transistors 840 and 860 can alternatively be referred to as nanowire, nanosheet, or nanoribbon transistors and the semiconductor strips that pass through the gate region can be referred to as nanowires, nanowires, or nanoribbons.

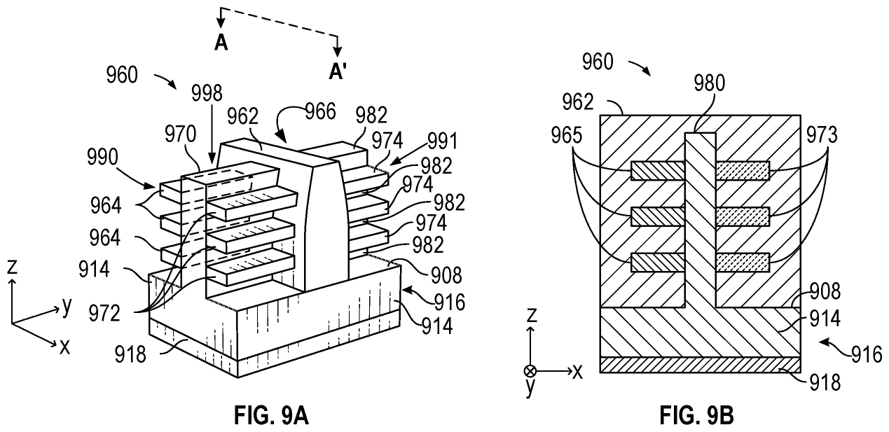

FIGS. 9A and 9B are perspective and cross-sectional views of an example forksheet transistor device. Generally, a forksheet transistor device comprises an n-type stacked GAAFET located next to a p-type stacked GAAFET with a dielectric region separating the nanoribbons (nanosheets, nanowires) forming the source, drain, and channel regions of the two GAAFETs. The forksheet transistor device 960 is formed on a substrate 916 having a surface 908. The n-type and p-type GAAFETs comprise three vertically stacked nanoribbons 1290 and 1291, respectively. Each nanoribbon 1290 of the n-type GAAFET is coplanar with a nanoribbon 1291 of the p-type GAAFET. The substrate 916 comprises an isolation region 914 located on top of a bulk region 918. A dielectric region 1298 separates the nanoribbons 1290 of the n-type GAAFET from the nanoribbons 1291 of the p-type GAAFET. A first portion 1270 of the dielectric region 1298 is positioned between n-type source regions 1264 and p-type source regions 1272, a second portion 1282 of the dielectric region 1298 is located between n-type drain regions 1266 (not viewable in FIG. 12A) and p-type drain regions 1274, and a third portion 1280 of the dielectric region 1298 is located between channel regions 1265 of nanoribbons 1290 and channel regions 1273 of nanoribbons 1291. In some embodiments, the dielectric region 1298 can be an extension of the substrate isolation region 1214. The gate 962 controls current flow between the n-type source 1264 and drain 966 regions, and the p-type source 972 and drain 974 regions.

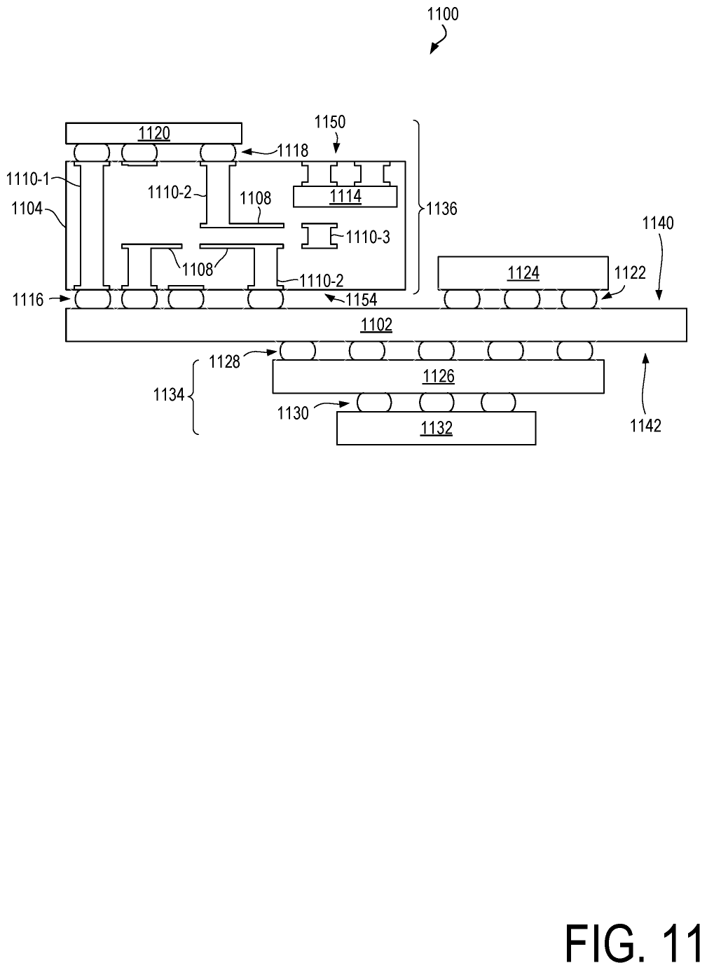

FIG. 9B is a cross-sectional view of the gate region of the forksheet transistor device 960 taken along the line A-A′ of FIG. 9A. Channel regions 965 connect n-type source regions 964 to n-type drain regions 966, channel regions 973 connect p-type source regions 972 to p-type drain regions 974, and the third portion 980 of the dielectric region 1298 separates the channel regions 965 from the channel regions 973 and connects the first portion 970 of the dielectric region 1298 to the second portion 1282 of the dielectric region 998. Thus, the forksheet transistor device 960 comprise an n-type transistor comprising n-type source regions 964, channel region 965, n-type drain regions 966, and gate 962; and a p-type transistor comprising p-type source regions 972, channel regions 973, p-type drain regions 974, and gate 962. The gate 962 is shared by the n-type and p-type GAAFETs. The forksheet transistor architecture can provide for reduced spacing between n-type and p-type S/D regions in adjacent GAAFETs relative to that in adjacent independent GAAFETs of the type illustrated in FIG. 11D. The forksheet transistor architecture can thus allow for increased transistor packing density relative to the packing of independent GAAFETs or increased active transistor width at the same transistor packing density as independent GAAFETs.

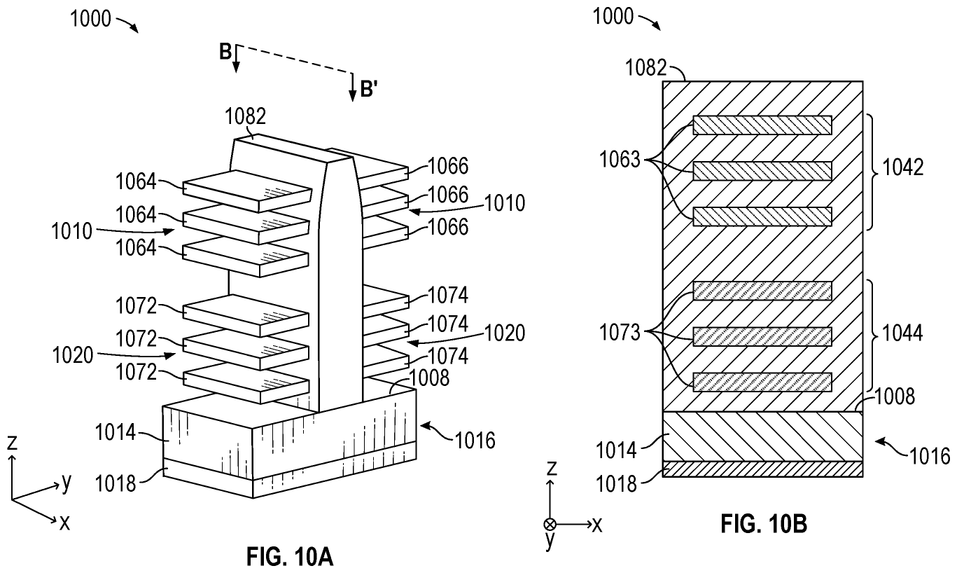

FIGS. 10A-10B are simplified perspective and cross-sectional views, respectively, of an example complementary field-effect-transistor (CFET) device. FIG. 10B is a cross-sectional view of the CFET device 1000 taken through the gate region and taken along the line B-B′ of FIG. 10A. The CFET device 1000 comprises vertically stacked GAAFETs 1042 and 1044. In FIGS. 10A and 10B, transistor 1042 is an n-type transistor, and transistor 1044 is a p-type transistor, but in other embodiments, a CFET device can comprise a p-type transistor located above an n-type transistor. The transistors 1042 and 1044 are formed on a substrate 1016 having a surface 1008. The substrate 1016 comprises an isolation region 1014 located on top of a bulk region 1018.

The n-type and p-type transistors 1042 and 1044 comprise a gate 1382 shared by both transistors that controls current flow between the source and drain regions of nanoribbons 1310 and 1320, respectively. The transistors 1342 and 1344 comprise three nanoribbons but the transistors of a CFET device can have any number of nanoribbons and different transistors of a CFET device can have a different number of nanoribbons. The n-type transistor 1342 comprises n-type source regions 1364 connected to n-type drain regions 1366 by channel regions 1363 and the p-type transistor 1344 comprises p-type source regions 1372 connected to p-type drain regions 1374 by channel regions 1373. The transistor stacking employed by the CFET device architecture can provide for improved transistor density in the x- and y-dimensions or increased transistor width at the same transistor density relative to other gate-all-around transistor architectures, such as those illustrated in FIGS. 11D, 12A, and 12B. In some embodiments, the CFET device 1300 can be formed monolithically, with the upper and lower transistors formed on the same substrate, or sequentially, with the lower transistor (e.g., 1344) formed on a first substrate and the upper transistor (e.g., 1342) formed on a second substrate, the upper transistor integrated with the lower transistor through transfer of the upper transistor from the second substrate to the first substrate.

Returning to FIG. 7, a transistor 740 may include a gate 722 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 740 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 740 along the source-channel-drain direction, the gate electrode may consist of a U-shaped structure that includes a bottom portion substantially parallel to the surface of the die substrate 702 and two sidewall portions that are substantially perpendicular to the top surface of the die substrate 702. In other embodiments, at least one of the metal layers that form the gate electrode may simply be a planar layer that is substantially parallel to the top surface of the die substrate 702 and does not include sidewall portions substantially perpendicular to the top surface of the die substrate 702. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 720 may be formed within the die substrate 702 adjacent to the gate 722 of individual transistors 740. The S/D regions 720 may be formed using an implantation/diffusion process or an etching/deposition process, for example. In the former process, dopants such as boron, aluminum, antimony, phosphorous, or arsenic may be ion-implanted into the die substrate 702 to form the S/D regions 720. An annealing process that activates the dopants and causes them to diffuse farther into the die substrate 702 may follow the ion-implantation process. In the latter process, the die substrate 702 may first be etched to form recesses at the locations of the S/D regions 720. An epitaxial deposition process may then be carried out to fill the recesses with material that is used to fabricate the S/D regions 720. In some implementations, the S/D regions 720 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 720 may be formed using one or more alternate semiconductor materials such as germanium or a group III-V material or alloy. In further embodiments, one or more layers of metal and/or metal alloys may be used to form the S/D regions 720.

Electrical signals, such as power and/or input/output (I/O) signals, may be routed to and/or from the devices (e.g., transistors 740) of the device layer 704 through one or more interconnect layers disposed on the device layer 704 (illustrated in FIG. 7 as interconnect layers 706-710). For example, electrically conductive features of the device layer 704 (e.g., the gate 722 and the S/D contacts 724) may be electrically coupled with the interconnect structures 728 of the interconnect layers 706-710. The one or more interconnect layers 706-710 may form a metallization stack (also referred to as an “ILD stack”) 719 of the integrated circuit device 700.

The interconnect structures 728 may be arranged within the interconnect layers 706-710 to route electrical signals according to a wide variety of designs; in particular, the arrangement is not limited to the particular configuration of interconnect structures 728 depicted in FIG. 7. Although a particular number of interconnect layers 706-710 is depicted in FIG. 7, embodiments of the present disclosure include integrated circuit devices having more or fewer interconnect layers than depicted.

In some embodiments, the interconnect structures 728 may include lines 728a and/or vias 728b filled with an electrically conductive material such as a metal. The lines 728a may be arranged to route electrical signals in a direction of a plane that is substantially parallel with a surface of the die substrate 702 upon which the device layer 704 is formed. For example, the lines 728a may route electrical signals in a direction in and out of the page and/or in a direction across the page from the perspective of FIG. 7. The vias 728b may be arranged to route electrical signals in a direction of a plane that is substantially perpendicular to the surface of the die substrate 702 upon which the device layer 704 is formed. In some embodiments, the vias 728b may electrically couple lines 728a of different interconnect layers 706-710 together.

The interconnect layers 706-710 may include a dielectric material 726 disposed between the interconnect structures 728, as shown in FIG. 7. In some embodiments, dielectric material 726 disposed between the interconnect structures 728 in different ones of the interconnect layers 706-710 may have different compositions; in other embodiments, the composition of the dielectric material 726 between different interconnect layers 706-710 may be the same. The device layer 704 may include a dielectric material 726 disposed between the transistors 740 and a bottom layer of the metallization stack as well. The dielectric material 726 included in the device layer 704 may have a different composition than the dielectric material 726 included in the interconnect layers 706-710; in other embodiments, the composition of the dielectric material 726 in the device layer 704 may be the same as a dielectric material 726 included in any one of the interconnect layers 706-710.

A first interconnect layer 706 (referred to as Metal 1 or “M1”) may be formed directly on the device layer 704. In some embodiments, the first interconnect layer 706 may include lines 728a and/or vias 728b, as shown. The lines 728a of the first interconnect layer 706 may be coupled with contacts (e.g., the S/D contacts 724) of the device layer 704. The vias 728b of the first interconnect layer 706 may be coupled with the lines 728a of a second interconnect layer 708.

The second interconnect layer 708 (referred to as Metal 2 or “M2”) may be formed directly on the first interconnect layer 706. In some embodiments, the second interconnect layer 708 may include via 728b to couple the lines 728 of the second interconnect layer 708 with the lines 728a of a third interconnect layer 710. Although the lines 728a and the vias 728b are structurally delineated with a line within individual interconnect layers for the sake of clarity, the lines 728a and the vias 728b may be structurally and/or materially contiguous (e.g., simultaneously filled during a dual-damascene process) in some embodiments.

The third interconnect layer 710 (referred to as Metal 3 or “M3”) (and additional interconnect layers, as desired) may be formed in succession on the second interconnect layer 708 according to similar techniques and configurations described in connection with the second interconnect layer 708 or the first interconnect layer 706. In some embodiments, the interconnect layers that are “higher up” in the metallization stack 719 in the integrated circuit device 700 (i.e., farther away from the device layer 704) may be thicker that the interconnect layers that are lower in the metallization stack 719, with lines 728a and vias 728b in the higher interconnect layers being thicker than those in the lower interconnect layers.

The integrated circuit device 700 may include a solder resist material 734 (e.g., polyimide or similar material) and one or more conductive contacts 736 formed on the interconnect layers 706-710. In FIG. 7, the conductive contacts 736 are illustrated as taking the form of bond pads. The conductive contacts 736 may be electrically coupled with the interconnect structures 728 and configured to route the electrical signals of the transistor(s) 740 to external devices. For example, solder bonds may be formed on the one or more conductive contacts 736 to mechanically and/or electrically couple an integrated circuit die including the integrated circuit device 700 with another component (e.g., a printed circuit board). The integrated circuit device 700 may include additional or alternate structures to route the electrical signals from the interconnect layers 706-710; for example, the conductive contacts 736 may include other analogous features (e.g., posts) that route the electrical signals to external components.

In some embodiments in which the integrated circuit device 700 is a double-sided die, the integrated circuit device 700 may include another metallization stack (not shown) on the opposite side of the device layer(s) 704. This metallization stack may include multiple interconnect layers as discussed above with reference to the interconnect layers 706-710, to provide conductive pathways (e.g., including conductive lines and vias) between the device layer(s) 704 and additional conductive contacts (not shown) on the opposite side of the integrated circuit device 700 from the conductive contacts 736.

In other embodiments in which the integrated circuit device 700 is a double-sided die, the integrated circuit device 700 may include one or more through silicon vias (TSVs) through the die substrate 702; these TSVs may make contact with the device layer(s) 704, and may provide conductive pathways between the device layer(s) 704 and additional conductive contacts (not shown) on the opposite side of the integrated circuit device 700 from the conductive contacts 736. In some embodiments. TSVs extending through the substrate can be used for routing power and ground signals from conductive contacts on the opposite side of the integrated circuit device 700 from the conductive contacts 736 to the transistors 740 and any other components integrated into the die 700, and the metallization stack 719 can be used to route I/O signals from the conductive contacts 736 to transistors 740 and any other components integrated into the die 700.

Multiple integrated circuit devices 700 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

FIG. 11 is a cross-sectional side view of an integrated circuit device assembly 1100 that may include any of the microelectronic assemblies disclosed herein. The integrated circuit device assembly 1100 includes a number of components disposed on a circuit board 1102 (which may be a motherboard, system board, mainboard, etc.). The integrated circuit device assembly 1100 includes components disposed on a first face 1140 of the circuit board 1102 and an opposing second face 1142 of the circuit board 1102; generally, components may be disposed on one or both faces 1140 and 1142.

In some embodiments, the circuit board 1102 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1102. In other embodiments, the circuit board 1102 may be a non-PCB substrate. The integrated circuit device assembly 1100 illustrated in FIG. 11 includes a package-on-interposer structure 1136 coupled to the first face 1140 of the circuit board 1102 by coupling components 1116. The coupling components 1116 may electrically and mechanically couple the package-on-interposer structure 1136 to the circuit board 1102, and may include solder balls (as shown in FIG. 11), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 1116 may serve as the coupling components illustrated or described for any of the substrate assembly or substrate assembly components described herein, as appropriate.

The package-on-interposer structure 1136 may include an integrated circuit component 1120 coupled to an interposer 1104 by coupling components 1118. The coupling components 1118 may take any suitable form for the application, such as the forms discussed above with reference to the coupling components 1116. Although a single integrated circuit component 1120 is shown in FIG. 11, multiple integrated circuit components may be coupled to the interposer 1104; indeed, additional interposers may be coupled to the interposer 1104. The interposer 1104 may provide an intervening substrate used to bridge the circuit board 1102 and the integrated circuit component 1120.

The integrated circuit component 1120 may be a packaged or unpacked integrated circuit product that includes one or more integrated circuit dies (e.g., the die 602 of FIG. 6, the integrated circuit device 700 of FIG. 7) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1120, a single monolithic integrated circuit die comprises solder bumps attached to contacts on the die. The solder bumps allow the die to be directly attached to the interposer 1104. The integrated circuit component 1120 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1120 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1120 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1120 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1104 may spread connections to a wider pitch or reroute a connection to a different connection. For example, the interposer 1104 may couple the integrated circuit component 1120 to a set of ball grid array (BGA) conductive contacts of the coupling components 1116 for coupling to the circuit board 1102. In the embodiment illustrated in FIG. 11, the integrated circuit component 1120 and the circuit board 1102 are attached to opposing sides of the interposer 1104; in other embodiments, the integrated circuit component 1120 and the circuit board 1102 may be attached to a same side of the interposer 1104. In some embodiments, three or more components may be interconnected by way of the interposer 1104.

In some embodiments, the interposer 1104 may be formed as a PCB, including multiple metal layers separated from one another by layers of dielectric material and interconnected by electrically conductive vias. In some embodiments, the interposer 1104 may be formed of an epoxy resin, a fiberglass-reinforced epoxy resin, an epoxy resin with inorganic fillers, a ceramic material, or a polymer material such as polyimide. In some embodiments, the interposer 1104 may be formed of alternate rigid or flexible materials that may include the same materials described above for use in a semiconductor substrate, such as silicon, germanium, and other group III-V and group IV materials. The interposer 1104 may include metal interconnects 1108 and vias 1110, including but not limited to through hole vias 1110-1 (that extend from a first face 1150 of the interposer 1104 to a second face 1154 of the interposer 1104), blind vias 1110-2 (that extend from the first or second faces 1150 or 1154 of the interposer 1104 to an internal metal layer), and buried vias 1110-3 (that connect internal metal layers).

In some embodiments, the interposer 1104 can comprise a silicon interposer. Through silicon vias (TSV) extending through the silicon interposer can connect connections on a first face of a silicon interposer to an opposing second face of the silicon interposer. In some embodiments, an interposer 1104 comprising a silicon interposer can further comprise one or more routing layers to route connections on a first face of the interposer 1104 to an opposing second face of the interposer 1104.

The interposer 1104 may further include embedded devices 1114, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1104. The package-on-interposer structure 1136 may take the form of any of the package-on-interposer structures known in the art. In embodiments where the interposer is a non-printed circuit board

The integrated circuit device assembly 1100 may include an integrated circuit component 1124 coupled to the first face 1140 of the circuit board 1102 by coupling components 1122. The coupling components 1122 may take the form of any of the embodiments discussed above with reference to the coupling components 1116, and the integrated circuit component 1124 may take the form of any of the embodiments discussed above with reference to the integrated circuit component 1120.

The integrated circuit device assembly 1100 illustrated in FIG. 11 includes a package-on-package structure 1134 coupled to the second face 1142 of the circuit board 1102 by coupling components 1128. The package-on-package structure 1134 may include an integrated circuit component 1126 and an integrated circuit component 1132 coupled together by coupling components 1130 such that the integrated circuit component 1126 is disposed between the circuit board 1102 and the integrated circuit component 1132. The coupling components 1128 and 1130 may take the form of any of the embodiments of the coupling components 1116 discussed above, and the integrated circuit components 1126 and 1132 may take the form of any of the embodiments of the integrated circuit component 1120 discussed above. The package-on-package structure 1134 may be configured in accordance with any of the package-on-package structures known in the art.

FIG. 12 is a block diagram of an example electrical device 1200 that may include one or more of the microelectronic assemblies disclosed herein. For example, any suitable ones of the components of the electrical device 1200 may include one or more of the integrated circuit device assemblies 1100, integrated circuit components 1120, integrated circuit devices 700, or integrated circuit dies 602 disclosed herein, and may be arranged in any of the microelectronic assemblies disclosed herein. A number of components are illustrated in FIG. 12 as included in the electrical device 1200, but any one or more of these components may be omitted or duplicated, as suitable for the application. In some embodiments, some or all of the components included in the electrical device 1200 may be attached to one or more motherboards mainboards, or system boards. In some embodiments, one or more of these components are fabricated onto a single system-on-a-chip (SoC) die.

Additionally, in various embodiments, the electrical device 1200 may not include one or more of the components illustrated in FIG. 12, but the electrical device 1200 may include interface circuitry for coupling to the one or more components. For example, the electrical device 1200 may not include a display device 1206, but may include display device interface circuitry (e.g., a connector and driver circuitry) to which a display device 1206 may be coupled. In another set of examples, the electrical device 1200 may not include an audio input device 1224 or an audio output device 1208, but may include audio input or output device interface circuitry (e.g., connectors and supporting circuitry) to which an audio input device 1224 or audio output device 1208 may be coupled.

The electrical device 1200 may include one or more processor units 1202 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1202 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1200 may include a memory 1204, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1204 may include memory that is located on the same integrated circuit die as the processor unit 1202. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1200 can comprise one or more processor units 1202 that are heterogeneous or asymmetric to another processor unit 1202 in the electrical device 1200. There can be a variety of differences between the processing units 1202 in a system in terms of a spectrum of metrics of merit including architectural, microarchitectural, thermal, power consumption characteristics, and the like. These differences can effectively manifest themselves as asymmetry and heterogeneity among the processor units 1202 in the electrical device 1200.

In some embodiments, the electrical device 1200 may include a communication component 1212 (e.g., one or more communication components). For example, the communication component 1212 can manage wireless communications for the transfer of data to and from the electrical device 1200. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1212 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1212 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1212 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1212 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1212 may operate in accordance with other wireless protocols in other embodiments. The electrical device 1200 may include an antenna 1222 to facilitate wireless communications and/or to receive other wireless communications (such as AM or FM radio transmissions).

In some embodiments, the communication component 1212 may manage wired communications, such as electrical, optical, or any other suitable communication protocols (e.g., IEEE 802.3 Ethernet standards). As noted above, the communication component 1212 may include multiple communication components. For instance, a first communication component 1212 may be dedicated to shorter-range wireless communications such as Wi-Fi or Bluetooth, and a second communication component 1212 may be dedicated to longer-range wireless communications such as global positioning system (GPS), EDGE, GPRS, CDMA, WiMAX, LTE, EV-DO, or others. In some embodiments, a first communication component 1212 may be dedicated to wireless communications, and a second communication component 1212 may be dedicated to wired communications.

The electrical device 1200 may include battery/power circuitry 1214. The battery/power circuitry 1214 may include one or more energy storage devices (e.g., batteries or capacitors) and/or circuitry for coupling components of the electrical device 1200 to an energy source separate from the electrical device 1200 (e.g., AC line power).

The electrical device 1200 may include a display device 1206 (or corresponding interface circuitry, as discussed above). The display device 1206 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1200 may include an audio output device 1208 (or corresponding interface circuitry, as discussed above). The audio output device 1208 may include any embedded or wired or wirelessly connected external device that generates an audible indicator, such speakers, headsets, or earbuds.

The electrical device 1200 may include an audio input device 1224 (or corresponding interface circuitry, as discussed above). The audio input device 1224 may include any embedded or wired or wirelessly connected device that generates a signal representative of a sound, such as microphones, microphone arrays, or digital instruments (e.g., instruments having a musical instrument digital interface (MIDI) output). The electrical device 1200 may include a Global Navigation Satellite System (GNSS) device 1218 (or corresponding interface circuitry, as discussed above), such as a Global Positioning System (GPS) device. The GNSS device 1218 may be in communication with a satellite-based system and may determine a geolocation of the electrical device 1200 based on information received from one or more GNSS satellites, as known in the art.

The electrical device 1200 may include an other output device 1210 (or corresponding interface circuitry, as discussed above). Examples of the other output device 1210 may include an audio codec, a video codec, a printer, a wired or wireless transmitter for providing information to other devices, or an additional storage device.

The electrical device 1200 may include an other input device 1220 (or corresponding interface circuitry, as discussed above). Examples of the other input device 1220 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1200 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1200 may be any other electronic device that processes data. In some embodiments, the electrical device 1200 may comprise multiple discrete physical components. Given the range of devices that the electrical device 1200 can be manifested as in various embodiments, in some embodiments, the electrical device 1200 can be referred to as a computing device or a computing system.

As used in this application and the claims, a list of items joined by the term “and/or” can mean any combination of the listed items. For example, the phrase “A, B and/or C” can mean A; B; C; A and B; A and C; B and C; or A, B and C. As used in this application and the claims, a list of items joined by the term “at least one of” can mean any combination of the listed terms. For example, the phrase “at “least one of A, B or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B and C” can mean A; B; C; A and B; A and C; B and C; or A, B, and C. Furthermore, as used in this application and the claims, a list of items joined by the term “one of” can mean any one of the listed items. For example, the phrase “one of A, B, and C” can mean A, B, or C.

As used in this application and the claims, the phrase “individual of” or “respective of” following by a list of items recited or stated as having a trait, feature, etc. means that all of the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

The following examples pertain to additional embodiments of technologies disclosed herein.

Example 1 includes an apparatus, comprising a first region comprising a first perovskite material; a second region comprising a second perovskite material and a dopant that is an n-type dopant for the second perovskite material; a first electrode positioned adjacent to the first region, the first electrode comprising a third perovskite material, the first region positioned between the first electrode and the second region; and a second electrode positioned adjacent to the second region, the second electrode comprising a fourth perovskite material, the second region positioned between the first region and the second electrode.

Example 2 includes the subject matter of Example 1, and wherein the first perovskite material comprises barium, titanium, and oxygen.

Example 3 includes the subject matter of Example 2, and wherein the first perovskite material further comprises zirconium, calcium, strontium, or hafnium.

Example 4 includes the subject matter of Example 2, and wherein the first perovskite material further comprises calcium and zirconium.

Example 5 includes the subject matter of Example 1, and wherein the first perovskite material comprises bismuth, iron, and oxygen.

Example 6 includes the subject matter of Example 1, and wherein the first perovskite material further comprises lanthanum or cobalt.

Example 7 includes the subject matter of Example 1, and wherein the first perovskite material comprises lithium, niobium, and oxygen.

Example 8 includes the subject matter of Example 1, and wherein the first perovskite material comprises potassium, niobium, and oxygen.

Example 9 includes the subject matter of Example 1, and wherein the first perovskite material comprises gadolinium, iron, and oxygen.

Example 10 includes the subject matter of Example 9, and wherein the first perovskite material further comprises lanthanum.

Example 11 includes the subject matter of any one of Example 1-10, wherein the second perovskite material comprises barium, strontium, and oxygen and the n-type dopant comprises lanthanum, antimony, or strontium.

Example 12 includes the subject matter of any one of Example 1-10, wherein the second perovskite material comprises strontium, tin, and oxygen, and wherein the n-type dopant comprises lanthanum, tantalum, neodymium, samarium, niobium, antimony, or lead.

Example 13 includes the subject matter of any one of Example 1-10, wherein the second perovskite material comprises strontium, titanium, and oxygen, and wherein the n-type dopant comprises lanthanum or vanadium.

Example 14 includes the subject matter of any one of Example 1-13, wherein the third perovskite material comprises strontium, vanadium, and oxygen; strontium, chromium, and oxygen; strontium, iron, and oxygen; sodium, tungsten, and oxygen; potassium, molybdenum, and oxygen; strontium, niobium, and oxygen; lanthanum, titanium, and oxygen; lanthanum, tungsten, and oxygen; strontium, ruthenium, and oxygen; niobium, strontium, titanium, and oxygen; or comprises lanthanum, strontium, manganese, and oxygen.

Example 15 includes the subject matter of any one of Example 1-13, wherein the fourth perovskite material comprises strontium, vanadium, and oxygen; strontium, chromium, and oxygen; strontium, iron, and oxygen; sodium, tungsten, and oxygen; potassium, molybdenum, and oxygen; strontium, niobium, and oxygen; lanthanum, titanium, and oxygen; lanthanum, tungsten, and oxygen; strontium, ruthenium, and oxygen; niobium, strontium, titanium, and oxygen; or comprises lanthanum, strontium, manganese, and oxygen.

Example 16 includes the subject matter of any one of Example 1-15, wherein the first perovskite material comprises one or more trap energy levels within, at 300 K, about 518 meV of a conduction band or a valence band of the first perovskite material.

Example 17 includes the subject matter of any one of Example 1-16, wherein the apparatus is a wafer.

Example 18 includes the subject matter of any one of Example 1-16, wherein the apparatus is part of a memory integrated circuit component.

Example 19 includes the subject matter of any one of Example 1-16, wherein the apparatus is an integrated circuit component.

Example 20 includes the subject matter of Example 19, and wherein the apparatus is part of a memory circuit of the integrated circuit component.

Example 21 includes the subject matter of Example 20, and further including a printed circuit board, the integrated circuit component attached to the printed circuit board.

Example 22 includes the subject matter of Example 21, and wherein the integrated circuit component is a first integrated circuit component, the apparatus further comprising a second integrated circuit component attached to the printed circuit board.

Example 23 includes the subject matter of Example 21, and further including a housing of a computing device enclosing the printed circuit board.

Example 24 includes a method, comprising forming of a first electrode comprising a first perovskite material; forming of a first region comprising a second perovskite material, the first region positioned adjacent to the first electrode; forming of a second region comprising a third perovskite material and an n-type dopant for the third perovskite material, the second region positioned adjacent to the first region, the first region positioned between the first electrode and the second region; and forming of a second electrode comprising a fourth perovskite material, the second electrode positioned adjacent to the second region, the second region positioned between the first region and the second electrode.

Example 25 includes the subject matter of Example 24, and wherein the second perovskite material comprises barium, titanium, and oxygen.

Example 26 includes the subject matter of Example 25, and wherein the second perovskite material further comprises zirconium, calcium, strontium, or hafnium.

Example 27 includes the subject matter of Example 24, and wherein the second perovskite material further comprises calcium and zirconium.

Example 28 includes the subject matter of Example 24, and wherein the second perovskite material comprises bismuth, iron, and oxygen.

Example 29 includes the subject matter of Example 24, and wherein the second perovskite material further comprises lanthanum or cobalt.

Example 30 includes the subject matter of Example 24, and wherein the second perovskite material comprises lithium, niobium, and oxygen.

Example 31 includes the subject matter of Example 24, and wherein the second perovskite material comprises potassium, niobium, and oxygen.

Example 32 includes the subject matter of Example 24, and wherein the second perovskite material comprises gadolinium, iron, and oxygen.

Example 33 includes the subject matter of Example 32, and wherein the second perovskite material further comprises lanthanum.

Example 34 includes the subject matter of any one of Example 24-33, wherein the third perovskite material comprises barium, strontium, and oxygen, and wherein the n-type dopant comprises lanthanum, antimony, or strontium.

Example 35 includes the subject matter of any one of Example 24-33, wherein the third perovskite material comprises strontium, tin, and oxygen, and wherein the n-type dopant comprises lanthanum, tantalum, neodymium, samarium, niobium, antimony, or lead.

Example 36 includes the subject matter of any one of Example 24-33, wherein the third perovskite material comprises strontium, titanium, and oxygen, and wherein the n-type dopant comprises lanthanum or vanadium.

Example 37 includes the subject matter of any one of Example 24-36, wherein the first perovskite material comprises strontium, vanadium, and oxygen; strontium, chromium, and oxygen; strontium, iron, and oxygen; sodium, tungsten, and oxygen; potassium, molybdenum, and oxygen; strontium, niobium, and oxygen; lanthanum, titanium, and oxygen; lanthanum, tungsten, and oxygen; strontium, ruthenium, and oxygen; niobium, strontium, titanium, and oxygen; or comprises lanthanum, strontium, manganese, and oxygen.

Example 38 includes the subject matter of any one of Example 24-36, wherein the fourth perovskite material comprises strontium, vanadium, and oxygen; strontium, chromium, and oxygen; strontium, iron, and oxygen; sodium, tungsten, and oxygen; potassium, molybdenum, and oxygen; strontium, niobium, and oxygen; lanthanum, titanium, and oxygen; lanthanum, tungsten, and oxygen; strontium, ruthenium, and oxygen; niobium, strontium, titanium, and oxygen; or comprises lanthanum, strontium, manganese, and oxygen.

Example 39 includes the subject matter of any one of Example 24-37, wherein the first electrode is formed on or above a surface of a substrate.

Example 40 includes the subject matter of Example 39, and wherein the substrate comprises silicon.

Example 41 includes the subject matter of any one of Example 24-40, further comprising forming a conductive trace of a interconnect layer, wherein the first electrode is formed after formation of the conductive trace, the first electrode positioned adjacent to the conductive trace.

Example 42 includes the subject matter of any one of Example 24-40, further comprising forming a conductive trace of an interconnect layer after formation of the second electrode, wherein the second electrode is positioned adjacent to the conductive trace and between the conductive trace and the second region.

Example 43 includes the subject matter of any one of claims 1-23, wherein the first electrode, the first region, the second, and the second electrode form a diode and a current density of the diode is about 1.0×10⁻³ A/cm² or greater at 300 K, wherein the current density is determined based on a cross-sectional area of the first region perpendicular to the direction of current flow through the first region.

Example 44 includes the subject matter if any one of claims 1-23, wherein a doping level of the n-type dopant in the second region is about 0.1% or less.

1. An apparatus, comprising:
a first region comprising a first perovskite material;
a second region comprising a second perovskite material and a dopant that is an n-type dopant for the second perovskite material;
a first electrode positioned adjacent to the first region, the first electrode comprising a third perovskite material, the first region positioned between the first electrode and the second region; and
a second electrode positioned adjacent to the second region, the second electrode comprising a fourth perovskite material, the second region positioned between the first region and the second electrode.

2. The apparatus of claim 1, wherein the first perovskite material comprises barium, titanium, and oxygen.

3. The apparatus of claim 2, wherein the first perovskite material further comprises:
zirconium;
calcium;
strontium;
hafnium; or
calcium and zirconium.

4. The apparatus of claim 1, wherein the first perovskite material comprises:
bismuth, iron, and oxygen;
bismuth, iron, oxygen, and lanthanum;
bismuth, iron, oxygen, and cobalt.
lithium, niobium, and oxygen;
potassium, niobium, and oxygen;
gadolinium, iron, and oxygen; or
gadolinium, iron, oxygen, and lanthanum.

5. The apparatus of claim 1, wherein the second perovskite material comprises barium, strontium, and oxygen and the n-type dopant comprises lanthanum, antimony, or strontium.

6. The apparatus of claim 1, wherein the second perovskite material comprises strontium, tin, and oxygen, and wherein the n-type dopant comprises lanthanum, tantalum, neodymium, samarium, niobium, antimony, or lead.

7. The apparatus of claim 1, wherein the second perovskite material comprises strontium, titanium, and oxygen, and wherein the n-type dopant comprises lanthanum or vanadium.

8. The apparatus of claim 1, wherein the third perovskite material and/or the fourth perovskite material comprises:
strontium, vanadium, and oxygen;
strontium, chromium, and oxygen;
strontium, iron, and oxygen;
sodium, tungsten, and oxygen;
potassium, molybdenum, and oxygen;
strontium, niobium, and oxygen;
lanthanum, titanium, and oxygen;
lanthanum, tungsten, and oxygen;
strontium, ruthenium, and oxygen;
niobium, strontium, titanium, and oxygen; or
comprises lanthanum, strontium, manganese, and oxygen.

9. The apparatus of claim 1, wherein the first perovskite material comprises one or more trap energy levels within, at 300 K, about 518 meV of a conduction band or a valence band of the first perovskite material.

10. The apparatus of claim 1, wherein the apparatus is a wafer.

11. The apparatus of claim 1, wherein the apparatus is an integrated circuit component.

12. The apparatus of claim 11, further comprising a printed circuit board, the integrated circuit component attached to the printed circuit board.

13. A method, comprising:
forming of a first electrode comprising a first perovskite material;
forming of a first region comprising a second perovskite material, the first region positioned adjacent to the first electrode;
forming of a second region comprising a third perovskite material and an n-type dopant for the third perovskite material, the second region positioned adjacent to the first region, the first region positioned between the first electrode and the second region; and
forming of a second electrode comprising a fourth perovskite material, the second electrode positioned adjacent to the second region, the second region positioned between the first region and the second electrode;
wherein the first electrode is formed on or above a surface of a substrate comprising silicon.

14. The method of claim 13, wherein the second perovskite material comprises: barium, titanium, and oxygen.

15. The method of claim 14, wherein the second perovskite material further comprises:
zirconium;
calcium;
strontium;
hafnium; or
calcium and zirconium.

16. The method of claim 13, wherein the second perovskite material comprises:
bismuth, iron, and oxygen;
bismuth, iron, oxygen, and lanthanum;
bismuth, iron, oxygen, and cobalt;
lithium, niobium, and oxygen;
potassium, niobium, and oxygen;
gadolinium, iron, and oxygen; or
gadolinium, iron, oxygen, and lanthanum.

17. The method of claim 13, wherein the third perovskite material comprises barium, strontium, and oxygen, and wherein the n-type dopant comprises lanthanum, antimony, or strontium.

18. The method of claim 13, wherein the third perovskite material comprises strontium, tin, and oxygen, and wherein the n-type dopant comprises lanthanum, tantalum, neodymium, samarium, niobium, antimony, or lead.

19. The method of claim 13, wherein the third perovskite material comprises strontium, titanium, and oxygen, and wherein the n-type dopant comprises lanthanum or vanadium.

20. The method of claim 13, wherein the first perovskite material and/or the fourth perovskite material comprises:
strontium, vanadium, and oxygen;
strontium, chromium, and oxygen;
strontium, iron, and oxygen;
sodium, tungsten, and oxygen;
potassium, molybdenum, and oxygen;
strontium, niobium, and oxygen;
lanthanum, titanium, and oxygen;
lanthanum, tungsten, and oxygen;
strontium, ruthenium, and oxygen;
niobium, strontium, titanium, and oxygen; or
comprises lanthanum, strontium, manganese, and oxygen.
